(19) United States
(12) Patent Application Publication
(10) Pub. No.: US 2008/0079009 A1
(43) Pub. Date: Apr. 3, 2008

(54) Semiconductor device

(75) Inventor: Seiji YAEGASHI, Yamanashi (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: EUDYNA DEVICES INC., Yamanashi (JP)

(21) Appl. No.: 11/905,429

(22) Filed: Oct. 1, 2007

(30) Foreign Application Priority Data
Oct. 2, 2006 (JP) 2006-270286

(51) Int. Cl. H01L 29/12

(52) U.S. Cl. 257/77; 257/E29.004

(57) ABSTRACT

A semiconductor device includes a substrate composed of 3C-SiC, a GaN-based semiconductor layer provided on the substrate, a first electrode provided on the GaN-based semiconductor layer, a second electrode coupled to the substrate, and a control electrode controlling a current flowing between the first electrode and the second electrode.

### BACKGROUND OF THE INVENTION

1. Field of the Invention

This invention generally relates to a semiconductor device, and in particular, relates to a semiconductor device having GaN-based semiconductor.

2. Description of the Related Art

A semiconductor device having gallium nitride (GaN) based semiconductor including GaN is used for a power element operating with a high frequency and high power. The GaN-based semiconductor is a semiconductor including Ga and N. The GaN-based semiconductor is, for example, a mixed crystal composed of AlGaN in which GaN is mixed with AlN (aluminum nitride), InGaN in which GaN is mixed with InN (indium nitride), or AlInGaN in which GaN, AlN and InN are mixed with each other.

It is necessary that the semiconductor device operate with a high voltage, if the semiconductor device is used as a power element. Therefore, a semiconductor device operating with a high voltage or a semiconductor device withstanding a high voltage has been developed. There is a semiconductor device (a vertical device) withstanding a high voltage in which a current flows between a first electrode on a GaN-based semiconductor layer on a substrate and a second electrode on the substrate and the current is controlled with a control electrode. In the vertical device, a drift layer and a substrate are provided between the control electrode and the second electrode. It is possible to manufacture the vertical device withstanding a high voltage by controlling a thickness of the drift layer and the substrate, a carrier concentration, and energy band gap suitably.

A substrate including SiC (silicon carbide) is used for a substrate on which the GaN-based semiconductor layer is to be formed. SiC may be composed of a hexagonal crystal (4H, 6H and so on) or a cubic crystal (3C). A SiC substrate composed of the hexagonal crystal has been used for the semiconductor device having a GaN-based semiconductor. Japanese Patent Application Publication No. 2004-189598 discloses a manufacturing method of 3C-SiC. A normally-off horizontal GaN-based semiconductor FET having a 3C-SiC substrate is disclosed in Masayuki Abe et al., IEICE TRANS. ELECTRON., Vol. E89-C, No. 7 Jul. 2006, pp. 1057-1063.

Kazuo Arai and Sadafumi Yoshida, “Principle and Application of SiC Element”, Ohmsha, Ltd., March 2003, p. 21 discloses an art where a hollow crystal defect is generated in the 4H-SiC or in the 6H-SiC because of a long period structure in a hexagonal crystal, the crystal defect being called a micro pipe and passing through a wafer.

In the vertical device including a GaN-based semiconductor, a current flows at an interface between a GaN-based semiconductor layer and a SiC substrate in a direction vertical to the interface. Therefore, there is a demand for reducing a contact resistance between the GaN-based semiconductor layer and the SiC substrate. And it is preferable that the vertical device withstands a high voltage when the vertical device is used as a power element.

### SUMMARY OF THE INVENTION

The present invention provides a semiconductor device that is a vertical device including GaN-based semiconductor, has a reduced contact resistance between a GaN-based semiconductor layer and a SiC substrate, and withstands a high voltage.

According to an aspect of the present invention, preferably, there is provided a semiconductor device including a substrate composed of 3C-SiC, a GaN-based semiconductor layer provided on the substrate, a first electrode provided on the GaN-based semiconductor layer, a second electrode connected to the substrate, and a control electrode controlling a current flowing between the first electrode and the second electrode.

With the above-mentioned configuration, the substrate is composed of 3C-SiC that has small energy band gap and hardly generates a micro pipe. Therefore, a contact resistance is reduced between the GaN-based semiconductor layer and the SiC substrate. And it is possible to obtain a high withstand voltage.

### BRIEF DESCRIPTION OF THE DRAWINGS

Preferred embodiments of the present invention will be described in detail with reference to the following drawings, wherein:

FIG. 1A through FIG. 1C illustrate a cross sectional view showing a manufacturing process of a FET in accordance with a first embodiment;

FIG. 2A through FIG. 2C illustrate a cross sectional view showing a manufacturing process of a FET in accordance with a first embodiment;

FIG. 3 illustrates a cross sectional view of a FET in accordance with a second embodiment;

FIG. 4A through FIG. 4C illustrate a cross sectional view showing a manufacturing process of a FET in accordance with a third embodiment; and

FIG. 5A and FIG. 5B illustrate a cross sectional view showing a manufacturing process of a FET in accordance with a fourth embodiment.

### DESCRIPTION OF THE PREFERRED EMBODIMENTS

A description will now be given, with reference to the accompanying drawings, of embodiments of the present invention.

### First Embodiment

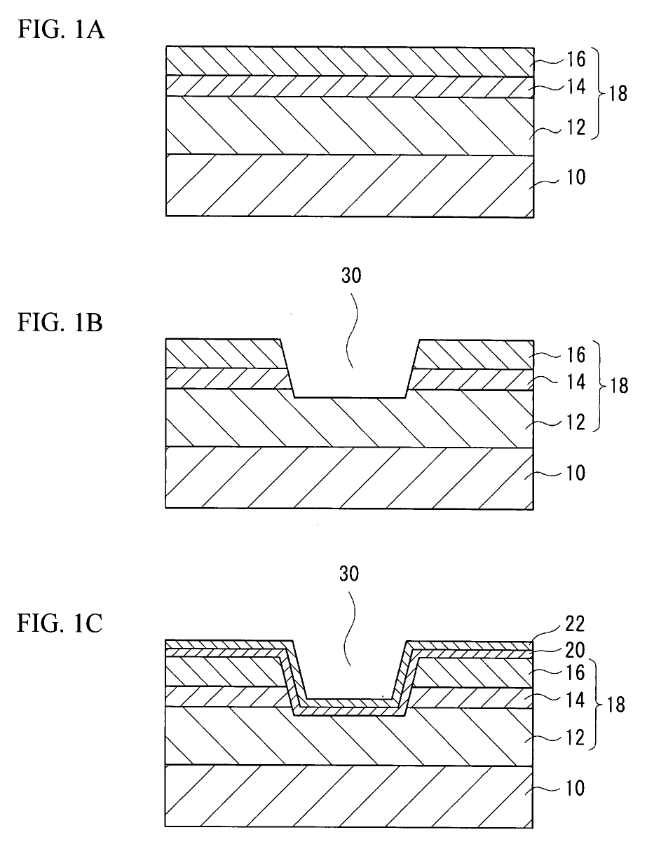

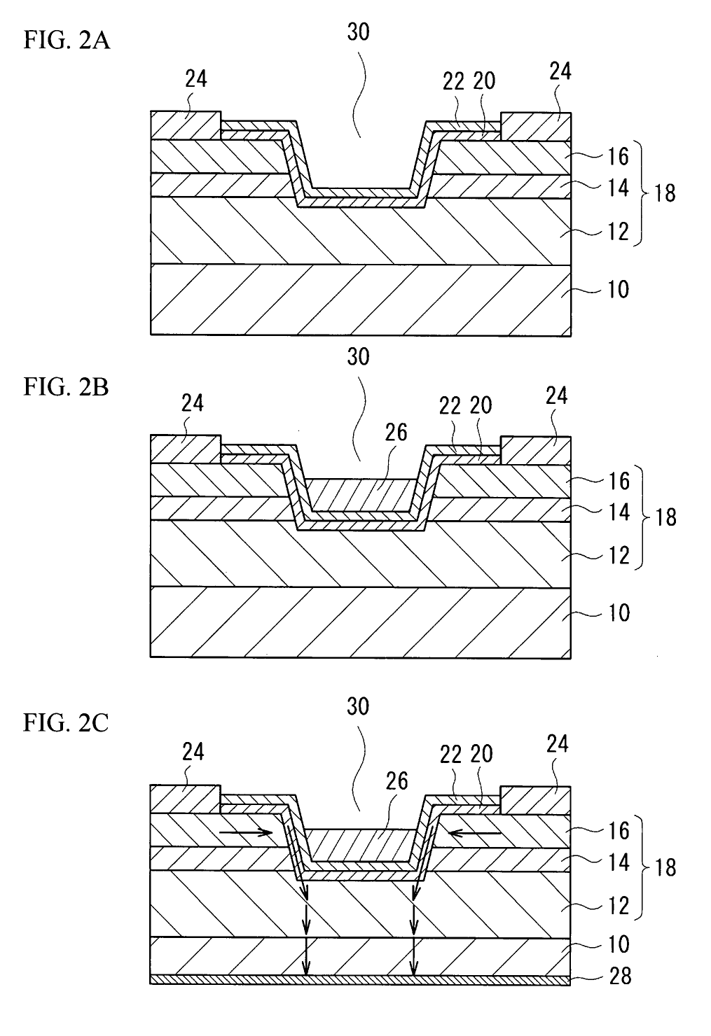

A first embodiment is an example of a FET having a GaN-based semiconductor in which a drift layer 12 composed of GaN is provided directly on a 3C-SiC substrate 10. FIG. 1A through FIG. 2C illustrate a cross sectional view showing a manufacturing process of a FET in accordance with the first embodiment. As shown in FIG. 1A, the N-type GaN drift layer 12, a P-type AlGaN electron control layer 14 and an N-type GaN cap layer 16 are formed on the 3C-SiC substrate 10 as a GaN-based semiconductor layer 18 with a MOCVD (Metal Organic Chemical Vapor Deposition) method so that the N-type GaN drift layer 12, the P-type AlGaN electron control layer 14 and the N-type GaN cap layer 16 are composed of a hexagonal crystal and have a (0 0 0 1) face serving as a main surface thereof. The 3C-SiC substrate 10 is composed of a cubic crystal and has a (1 1 1) face serving as a main surface thereof. The 3C-SiC substrate 10 has a dopant of N and has a carrier concentration of more than 10¹⁸ cm⁻³. The drift layer 12 grows with use of NH₃ (ammonia) and TMG (trimethyl gallium) at a growth temperature of 1000 degrees C. to 1100 degrees C. The drift layer 12 has a thickness of more than 3 μm and has a carrier (Si) concentration of 10¹⁵ cm⁻³ to 10¹⁶ cm⁻³. The electron control layer 14 grows with use of TMG and TMAL (trimethyl aluminum) at a growth temperature of 1050 degrees C. to 1200 degrees C. The electron control layer 14 has a thickness of 200 nm, has a carrier (magnesium) concentration of approximately 10¹⁸ cm⁻³ and has a composition of Al_{0.25}Ga_{0.75}N. The cap layer 16 grows with use of NH₃ and TMG at a growth temperature of 900 degrees C. to 1100 degrees C. The cap layer 16 has a thickness of 500 nm and has a carrier (Si) concentration of 10¹⁸ cm⁻³ to 10¹⁹ cm⁻³.

As shown in FIG. 1B, a recess 30 extending to the drift layer 12 is formed in the GaN-based semiconductor layer 18 with a chlorine-based dry etching. As shown in FIG. 1C, an I-type GaN electron transit layer 20 and an I-type AlN barrier layer 22 are formed on a side face and a bottom face of the recess 30 and on the cap layer 16. Thus, the GaN electron transit layer 20 and the AlN barrier layer 22 are formed on a side face of the electron control layer 14. The electron transit layer 20 and the barrier layer 22 have a thickness of 10 nm to 100 nm.

As shown in FIG. 2A, the electron transit layer 20 and the barrier layer 22 are eliminated in an area where a source electrode 24 (a first electrode) is to be formed. The source electrode 24 is formed on the cap layer 16 (on the GaN-based semiconductor layer 18) with a vacuum evaporation method and a lift off method. The source electrode 24 is composed of Ti/Al or Ti/Au.

As shown in FIG. 2B, a gate electrode 26 (a control electrode) is formed in the recess 30 with the vacuum evaporation method and the lift off method. The gate electrode 26 is composed of Ni/Al or Ni/Au. Thus, the gate electrode 26 is formed on a side face of the barrier layer 22 facing the electron control layer 14.

As shown in FIG. 2C, the substrate 10 is grinded so that the thickness of the substrate 10 is less than 200 μm. A drain electrode 28 (a second electrode) is formed so as to contact the bottom of the substrate 10 with the vacuum evaporation method and the lift off method. The drain electrode 28 is composed of Ti/Al or Ti/Au.

As shown at an arrow in FIG. 2C, an electron injected from the source electrode 24 to the cap layer 16 passes through the electron transit layer 20 because the electron control layer 14 is of P-type and barriers the electron in the FET in accordance with the first embodiment. After that, the electron passes through the drift layer 12 and the substrate 10 and gets at the drain electrode 28. The gate electrode 26 controls a current flowing between the source electrode 24 and the drain electrode 28. In other words, the gate electrode 26 is provided on the GaN-based semiconductor layer and controls a current flowing in the GaN-based semiconductor layer 18. Thus, the FET operates.

A hexagonal 4H-SiC or a hexagonal 6H-SiC is appropriate for an insulating substrate, because the 4H-SiC or the 6H-SiC has a large energy band gap of approximately 3.0 eV. However, a discontinuous energy ΔEc of conduction band is large at an interface between the 4H-SiC or the 6H-SiC and the GaN layer. Therefore, when a GaN layer is formed on a SiC layer, a contact resistance at an interface between the SiC and the GaN is enlarged in a direction vertical to the interface and an electrical conductivity is degraded.

The 3C-SiC has energy band gap of approximately 2.2 eV. The ΔEc is small at an interface between the substrate 10 and the GaN drift layer 12, when the GaN drift layer 12 is formed on the substrate 10 composed of 3C-SiC, as is the case of the first embodiment. In this case, the contact resistance between the substrate 10 and the drift layer 12 is reduced. And conductivity of a current is improved between the source electrode 24 and the drain electrode 28.

As mentioned above, a micro pipe is generated in the 4H-SiC substrate and the 6H-SiC substrate. When the GaN-based semiconductor layer 18 is grown on the 4H-SiC substrate or on the 6H-SiC substrate, a defect is generated in the GaN-based semiconductor layer 18 according to the micro pipe because of a defect of the base substrate. Some defects according to the micro pipe are extinguished in the growth process. However, it is not possible to extinguish all of the defects according to the micro pipe. A direction, in which an electrical field is applied between the gate electrode 26 and the drain electrode 28 in the vertical device shown in FIG. 2C, is approximately vertical to the main surface of the substrate 10. In a case of the 4H-SiC substrate or the 6H-SiC substrate having a (0 0 0 1) face serving as a main surface thereof, the micro pipe is generated in a direction vertical to the main surface of the substrate 10. A leak current is increased and it is difficult to achieve a high withstand voltage, because the micro pipe is generated substantially parallel to the electrical field direction. That is, in a case where the 4H-SiC substrate or the 6H-SiC substrate is applied to the vertical device, the micro pipe has an adverse effect to the vertical device. In this case, the leak current flows through the micro pipe. It is therefore preferable that the number of the micro pipe is reduced.

On the other hand, the micro pipe is hardly generated in a case where the GaN-based semiconductor layer 18 is provided on the 3C-SiC substrate 10. As mentioned above, the generation of the micro pipe is caused by a long-period structure of the 4H-SiC substrate or the 6H-SiC substrate having the hexagonal crystal structure. Therefore, the micro pipe is hardly generated in a 3C-SiC having a short-period structure. For example, a concentration of the micro pipe in the 4H-SiC or the 6H-SiC is more than 10/cm⁻³. In contrast, the concentration of the micro pipe in the 3C-SiC is 0 to 1/cm⁻³. Therefore, the micro pipe causing a leak current is hardly generated between the gate electrode 26 and the drain electrode 28 in the vertical device in accordance with the first embodiment. And the number of the micro pipe is small in the electron transit layer 20 controlled by the gate electrode 26. It is possible to apply a high electrical voltage between the gate electrode 26 and the drain electrode 28 where the leak current from the electron transit layer 20 is to be reduced. Accordingly, it is possible to achieve a high withstand voltage.

Further, it is preferable that the substrate 10 is composed of a cubic crystal and has a (1 1 1) face serving as a main surface thereof, and the GaN-based semiconductor layer 18 is composed of a hexagonal crystal and has a (0 0 0 1) face serving as a main surface thereof. It is possible to form a 3C-GaN cubic crystal (1 1 1) or a GaN hexagonal crystal (0 0 0 1) on a 3C-SiC substrate being composed of a cubic crystal and having a (1 1 1) face serving as a main surface thereof. A piezoelectrical charge tends to be generated in a case where the GaN-based semiconductor layer 18 is composed of a hexagonal crystal and has a (0 0 0 1) face serving as a main surface thereof. It is therefore possible to form a highly concentrated 2DEG (2 dimension electron gas) with use of the piezoelectrical charge. And it is possible to reduce a contact resistance between the source electrode 24 and the cap layer 16.

### Second Embodiment

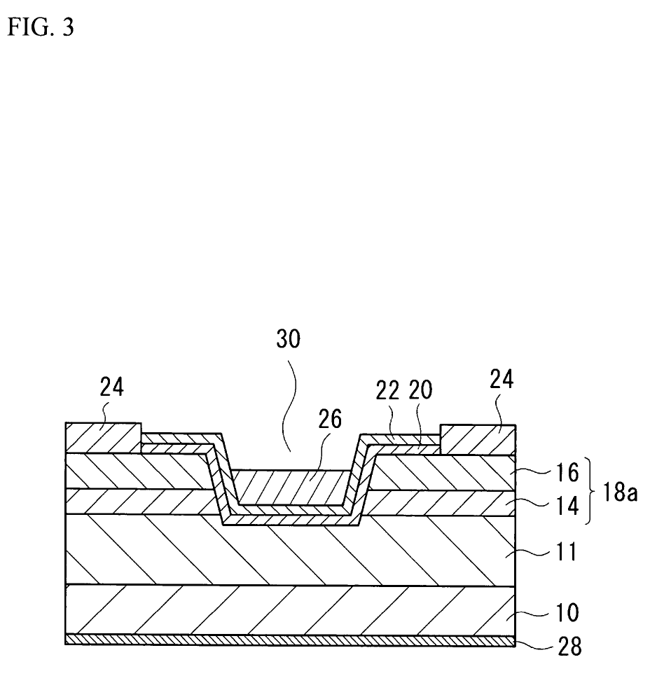

A second embodiment is a case where a 3C-SiC drift layer 11 is provided. As shown in FIG. 3, the 3C-SiC drift layer 11 is provided instead of the GaN drift layer 12. The 3C-SiC drift layer 11 is composed of a cubic crystal and has a (1 1 1) face serving as a main surface thereof. The AlGaN electron control layer 14 and the cap layer 16 are formed on the 3C-SiC drift layer 11 as a GaN-based semiconductor layer 18a with the MOCVD method. The GaN-based semiconductor layer 18a is composed of a hexagonal crystal and has a (0 0 0 1) face serving as a main surface thereof. Other components are in common with the first embodiment.

It is thus possible to form the 3C-SiC drift layer 11 between the substrate 10 and the GaN-based semiconductor layer 18a. SiC has a dielectric strength voltage approximately ten times as that of Si. It is therefore possible to restrict the generation of the defect caused by the micro pipe in the 3C-SiC drift layer 11 and is possible to increase the thickness of the 3C-SiC drift layer 11, when the 3C-SiC substrate 10 is used. It is therefore possible to achieve a high withstand voltage. In the second embodiment, a contact resistance between the substrate 10 and the GaN-based semiconductor layer 18a is small. And it is possible to manufacture a vertical device withstanding a high voltage.

As shown in the second embodiment, the GaN-based semiconductor layer 18a may have a bottom layer other than the GaN layer. For example, it is possible to obtain a better electrical conductivity between the first electrode and the second electrode with use of a 3C-SiC substrate, in a case where the bottom layer is composed of such as GaN and the ΔEc is large between the bottom layer and a hexagonal SiC. An effect of resistance reduction is obtained when the bottom layer of the GaN-based semiconductor layer 18 is a GaN semiconductor layer or a GaN-based semiconductor layer having ΔEc smaller than that of the GaN semiconductor layer as is the case of the first embodiment.

### Third Embodiment

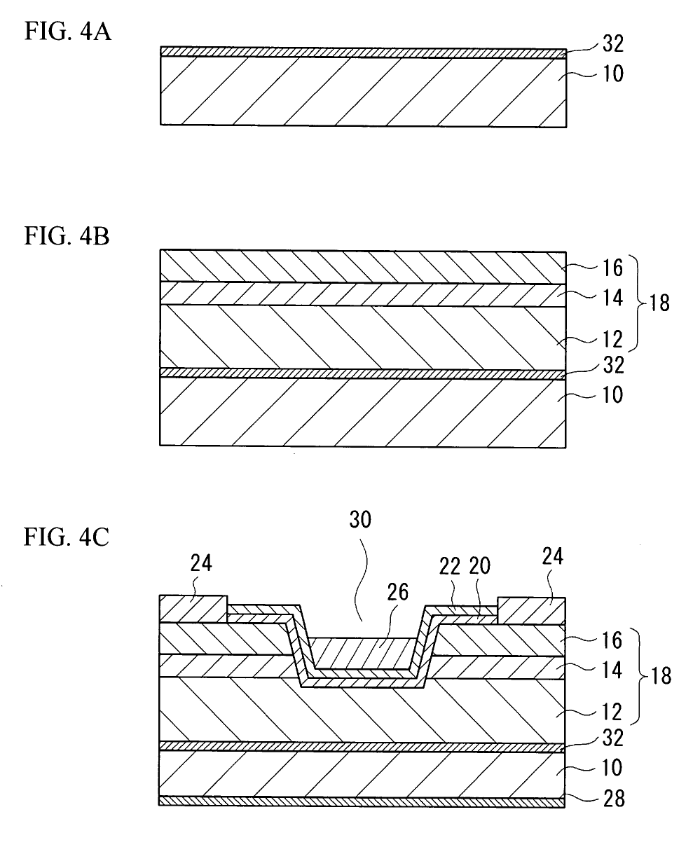

A third embodiment is a case where a crystal nucleation layer 32 is provided between the GaN-based semiconductor layer 18 and the 3C-SiC substrate 10. As shown in FIG. 4A, the crystal nucleation layer 32 composed of AlInGaN is formed so as to contact the substrate 10 with the MOCVD method. The crystal nucleation layer 32 may be composed of ZnO (zinc oxide) or ZrB₂ (zirconium boride) in addition to AlInGaN. It is thus preferable that a material lattice-matched to the GaN layer is used.

As shown in FIG. 4B, the GaN drift layer 12 is formed on the crystal nucleation layer 32 so as to contact the crystal nucleation layer 32. And the GaN-based semiconductor layer 18 is formed, similarly to the first embodiment. As shown in FIG. 4C, the electron transit layer 20, the barrier layer 22, the source electrode 24, the gate electrode 26 and the drain electrode 28 are formed with a process in accordance with the first embodiment. And a FET in accordance with the third embodiment is manufactured.

A seed crystal to form the GaN layer is hardly generated on the surface of the SiC substrate 10 when the GaN layer is grown on the SiC substrate 10 directly. And so, the crystal nucleation layer 32 is formed on the substrate 10 and the drift layer 12 is formed on the crystal nucleation layer 32 as shown in the third embodiment. It is thus possible to grow the crystal nucleation layer 32 on the substrate 10 easily. And it is possible to grow the GaN drift layer 12 easily because the seed crystal is generated on the crystal nucleation layer 32. The crystal nucleation layer 32 forms a seed crystal more easily when the crystal nucleation layer 32 includes more AlN, if the AlInGaN is used for the crystal nucleation layer 32. However, energy band gap of the crystal nucleation layer 32 is enlarged when the crystal nucleation layer 32 includes more AlN. The energy band gap may barrier a current flowing vertically. It is therefore preferable that the crystal nucleation layer 32 is composed of a mixed crystal including InN and the energy band gap of the crystal nucleation layer 32 is approximately as same as that of GaN. The thickness of the crystal nucleation layer 32 may be set so that the crystal nucleation layer 32 generates a seed crystal. For example, the crystal nucleation layer 32 has a thickness of 5 nm to 100 nm. It is preferable that the crystal nucleation layer 32 has a carrier concentration of 10¹⁷ cm⁻³ to 10¹⁸ cm⁻³ so that a current flows.

### Fourth Embodiment

A fourth embodiment is a case where a plurality of a crystal nucleation layers 32a is provided so as to contact the substrate 10 and to be separated away from each other, and the GaN drift layer 12 is contacted to the substrate 10 between the crystal nucleation layers 32a.

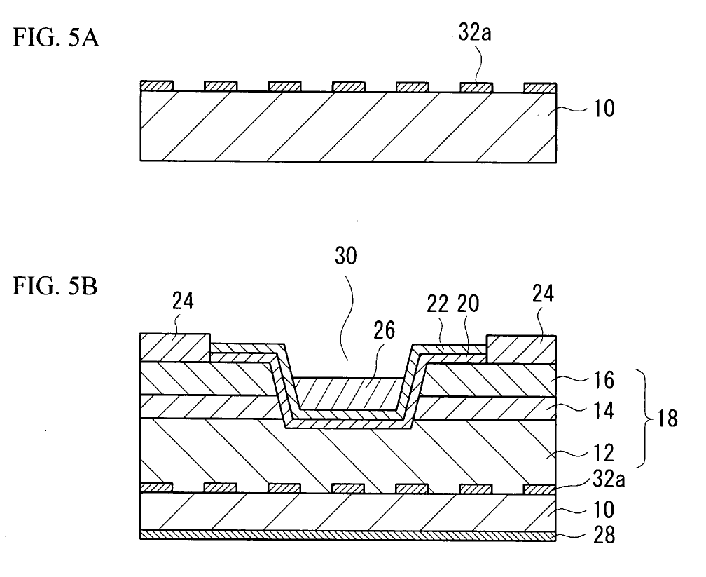

As shown in FIG. 5A, an etching treatment is performed so that the crystal nucleation layer 32 is divided and a plurality of the crystal nucleation layers 32a is formed after the process shown in FIG. 4A in accordance with the third embodiment.

As shown in FIG. 5B, the GaN-based semiconductor layer 18 is formed with the MOCVD method similarly to the first embodiment. In this case, the GaN drift layer 12 is formed so as to contact the substrate 10 between the crystal nucleation layers 32a. Other components are in common with the third embodiment shown in FIG. 4C.

In the fourth embodiment, GaN grows upward and in a lateral direction on the crystal nucleation layer 32a when the GaN drift layer 12 grows. The GaN layer grows in the lateral direction on the crystal nucleation layer 32a. Therefore, it is not necessary that the crystal nucleation layer 32 cover whole area of the substrate 10. It is preferable that an interval between each of the crystal nucleation layers 32a in accordance with the fourth embodiment is set so that the GaN grows laterally. It is preferable that the interval is 1 μm to 10 μm.

In accordance with the fourth embodiment, the crystal nucleation layer 32a generates a seed crystal to form the GaN drift layer 12. On the other hand, a current flows directly between the GaN drift layer 12 and the substrate 10, because the GaN drift layer 12 and the substrate 10 are directly contacted to each other between the each of the crystal nucleation layers 32a. Therefore, it is possible to restrict an increase of the contact resistance in a case where the crystal nucleation layer 32 is provided as shown in the third embodiment. It is preferable that the crystal nucleation layer 32a has a carrier concentration of 10¹⁷ cm⁻³ to 10¹⁸ cm⁻³ because the crystal nucleation layer 32a reduces the contact resistance. In addition, the crystal nucleation layer 32a may be provided in a recess formed in the substrate 10.

Another transistor, in which a current flows between the first electrode on the GaN-based semiconductor layer and the second electrode on the substrate, achieves the effect of the present invention, although the first embodiment through the fourth embodiment are an example of a vertical FET. For example, the present invention may be applied to a bipolar transistor in which the first electrode is an emitter electrode, the second electrode is a collector electrode and the control electrode is a base electrode or may be applied to an IGBT (an insulated gate bipolar transistor) in which the first electrode is an emitter electrode, the second electrode is a collector electrode and the control electrode is a gate electrode.

While the above description constitutes the preferred embodiments of the present invention, it will be appreciated that the invention is susceptible of modification, variation and change without departing from the proper scope and fair meaning of the accompanying claims.

The present invention is based on Japanese Patent Application No. 2006-270286 filed on Oct. 2, 2006, the entire disclosure of which is hereby incorporated by reference.

What is claimed is:

1. A semiconductor device comprising:
a substrate composed of 3C-SiC;
a GaN-based semiconductor layer provided on the substrate;
a first electrode provided on the GaN-based semiconductor layer;
a second electrode connected to the substrate; and
a control electrode controlling a current flowing between the first electrode and the second electrode.

2. The semiconductor device as claimed in claim 1 further comprising a drift layer that is composed of GaN or 3C-SiC and is provided between the substrate and the GaN-based semiconductor layer.

3. The semiconductor device as claimed in claim 1, wherein:
the substrates is composed of a cubic crystal and has a (1 1 1) face serving as a main surface thereof; and
the GaN-based semiconductor layer is composed of a hexagonal crystal and has a (0 0 0 1) face serving as a main surface thereof.

4. The semiconductor device as claimed in claim 1 further comprising a crystal nucleation layer that is contacted to the substrate and is composed of a compound material lattice-matched to a GaN material.

5. The semiconductor device as claimed in claim 4 further comprising a plurality of the crystal nucleation layers that are separated away from each other and are contacted to the substrate.

6. The semiconductor device as claimed in claim 1, wherein the drift layer and the GaN-based semiconductor layer are grown by a MOCVD method.

7. The semiconductor device as claimed in claim 1, wherein the control electrode is provided on the GaN-based semiconductor layer and controls a current flowing into the GaN-based semiconductor layer.
